(19) United States
(12) Patent Application Publication
(10) Pub. No.: US 2025/0008663 A1
(43) Pub. Date: Jan. 2, 2025

(54) DISPLAY MODULE AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Shaopeng Li, Beijing (CN); Weiben Zhang, Beijing (CN); Jianhua Shu, Beijing (CN); Tianjun Deng, Beijing (CN); Peng Wang, Beijing (CN); Rongkun Fan, Beijing (CN); Bilun Zhang, Beijing (CN); Jialin Wang, Beijing (CN); Fei Li, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 18/702,389

(22) PCT Filed: Aug. 9, 2023
(86) PCT No.: PCT/CN2023/111921

§ 371 Date: Apr. 18, 2024

(30) Foreign Application Priority Data
Aug. 24, 2022 (CN) 202211018125.8

(51) Int. Cl. H05K 1/18; H05K 1/02

(52) U.S. Cl. CPC H05K 1/189; H05K 1/028; H05K 2201/10128

(57) ABSTRACT

A display module is provided, which includes a display panel and a flexible circuit board bound to the display panel. The display panel includes a display area, a binding area, and a bending area arranged between the display area and the binding area. The bending area is bent to enable the binding area to be located at a backlight side of the display area. The flexible circuit board includes a bending portion, and a first portion and a second portion arranged at two opposite sides of the bending portion respectively. The first portion is bound to the binding area, and an orthographic projection of the first portion onto the binding area is located within the binding area. The bending portion is bent to enable the second portion to be stacked at a side of the first portion distal to the display panel. A display device is also provided.

### CROSS-REFERENCE TO RELATED APPLICATION

The present application claims the priority to the Chinese patent application No. 202211018125.8 filed in China on Aug. 24, 2022, a disclosure of which is incorporated herein by reference in its entirety.

### TECHNICAL FIELD

The present disclosure relates to the field of display product manufacturing technologies, in particular to a display module and display device.

### BACKGROUND

With the development in the Organic Light-Emitting Diode (OLED) market, insufficient battery life remains a common issue across the industry. This is particularly pronounced for mid-sized foldable mobile phone products. The battery capacity has become a pain point that hinders their development. To address this, manufacturers of foldable devices have turned to a technique known as reverse bonding to enhance battery space capacity. However, with reverse bonding, the Flexible Printed Circuit (FPC) is stacked directly above the lower border of the display module. To accommodate the FPC's dimension, the size of the product's lower border must be increased. Unfortunately, this trade-off results in several challenges: inability to achieve a narrow border, reduced product competitiveness, low layout rate of the display module, and decreasing of the EAC cut count (the number of cuts made in the display module substrate).

### SUMMARY

In view of the above technical problem, the present disclosure provides a display module and a display device, which solves the problem that it is unable to achieve a narrow border due to the limitation of the flexible circuit board being bound to the display panel in an opposite direction.

An object of the embodiments of the present disclosure provides a display panel and a flexible circuit board bound to the display panel, the display panel includes a display area, a binding area, and a bending area arranged between the display area and the binding area, the bending area is bent to enable the binding area to be located at a backlight side of the display area,
wherein the flexible circuit board includes a bending portion, a first portion and a second portion, the first portion and the second portion are arranged at opposite sides of the bending portion respectively, the first portion is bound to the binding area, an orthographic projection of the first portion onto the binding area is located within the binding area, the bending portion is bent to enable the second portion to be stacked at a side of the first portion distal to the display panel.

Optionally, the bending portion includes a single circuit layer, the first portion includes two or more circuit layers, and the second portion includes two or more circuit layers.

Optionally, the first portion includes a main body and a binding portion extending from the main body toward a direction away from the bending portion, the binding portion is bound to an end of the binding area distal to the bending area, and the bending portion is arranged at a side of the first portion proximate to the bending area.

Optionally, an electronic device is arranged between the first portion and the second portion.

Optionally, the first portion has a first surface facing the second portion, the second portion has a second surface facing the first portion, a first electronic device is arranged on the first surface, and a second electronic device is arranged on the second surface, the first electronic devices and the second electronic devices are arranged in an alternating manner.

Optionally, an orthographic projection of the first electronic device onto the second surface is located between two adjacent second electronic devices.

Optionally, in a direction perpendicular to the first surface, the first electronic device at least partially overlaps with the second electronic device, or there is a gap between the first electronic device and the second electronic device.

Optionally, in a direction parallel to the first surface, there is a gap between the first electronic device and the second electronic device that are adjacent to each other, or an insulation layer is arranged on a peripheral surface of the first electronic device, and/or an insulation layer is arranged on a peripheral surface of the second electronic device.

Optionally, an orthographic projection of the second portion onto the first portion is located within a first region on the first portion, and the first portion also has a second region for arranging the electronic device; in a first direction, the second region is adjacent to the first region, or the second region partially overlaps with the first region, wherein the first direction is from the bending portion toward the first portion, and the first direction is parallel to the first surface.

Optionally, the electronic device is fixed to the corresponding first portion or second portion by an adhesive layer; in a direction perpendicular to the first surface, a bending radius of the bending portion is greater than or equal to half of a sum of a thickness of the adhesive layer and a thickness of the corresponding electronic device.

Optionally, the bending portion includes an arc-shaped region, a first planar region and a second planar region, the first planar region and the second planar region are arranged at two opposite sides of the arc-shaped region respectively; in a direction perpendicular to the first surface, a supporting adhesive layer is arranged between the first planar region and the second planar region.

Optionally, a side surface of the supporting adhesive layer proximate to the arc-shaped region, a bending start point of the arc-shaped region and a bending end point of the arc-shaped region are arranged in a same plane that is perpendicular to the first surface.

Optionally, a first protective adhesive layer is arranged at a side of the first portion proximate to the second portion, a second protective adhesive layer is arranged at a side of the second portion proximate to the first portion, the electronic devices are arranged on the first protective adhesive layer and/or the second protective adhesive layer, and a thickness of the supporting adhesive layer is greater than or equal to a thickness of the electronic device in a direction perpendicular to the first surface.

Another object of the embodiments of the present disclosure is to provide a display device including the above display module.

The beneficial effects of the present disclosure are as follows: the flexible circuit board is divided into a bending portion, and a first portion and a second portion arranged at two opposite sides of the bending portion respectively, and the bending portion is bent to enable the second portion to be stacked at a side of the first portion distal to the display panel. As a result, it is able to reduce a size of the flexible circuit board and achieve a narrow border.

### BRIEF DESCRIPTION OF THE DRAWINGS

FIG. 1 shows a schematic diagram of conventional binding of a flexible circuit board in related art;

FIG. 2 shows a schematic diagram of reverse binding of a flexible circuit board in related art;

FIG. 3 shows a first schematic diagram of a structure of a display module in embodiments of the present disclosure;

FIG. 4 shows a layout diagram of the flexible circuit board according to the conventional binding method;

FIG. 5 shows a layout diagram of the flexible circuit board according to the present disclosure;

FIG. 6 shows another schematic diagram of the structure of the display module in embodiments of the present disclosure;

FIG. 7 shows a first schematic diagram of the flexible circuit board in embodiments of the present disclosure;

FIG. 8 shows a second schematic diagram of the flexible circuit board in embodiments of the present disclosure;

FIG. 9 shows a third schematic diagram of the flexible circuit board in embodiments of the present disclosure;

FIG. 10 shows a first schematic diagram of the flexible circuit board bound to a display panel in embodiments of the present disclosure;

FIG. 11 shows a first schematic diagram of a bending portion that has been bended in embodiments of the present disclosure;

FIG. 12 shows a schematic diagram of arranging a protective adhesive layer in embodiments of the present disclosure;

FIG. 13 shows a schematic diagram that a cover plate has been attached in embodiments of the present disclosure;

FIG. 14 shows a second schematic diagram of the flexible circuit board bound to the display panel in embodiments of the present disclosure;

FIG. 15 shows a second schematic diagram of a bending portion that has been bended in embodiments of the present disclosure;

FIG. 16 shows a first schematic diagram of a lower border that has been cut in embodiments of the present disclosure;

FIG. 17 shows a schematic diagram that a supporting structure has been attached in embodiments of the present disclosure;

FIG. 18 shows a third schematic diagram of the flexible circuit board bound to the display panel in embodiments of the present disclosure.

### DETAILED DESCRIPTION

In order to make the object, technical solutions and advantages of embodiments of the present disclosure clearer, the technical solutions of the embodiments of the present disclosure will be clearly and completely described. Obviously, the described embodiments are only a part of the embodiments of the present disclosure, rather than all of them. Based on the described embodiments of the present disclosure, all other embodiments obtained by those of ordinary skill in the art shall fall within the protection scope of the present disclosure.

In the description of the present disclosure, it should be noted that the terms such as “center”, “up”, “down”, “left”, “right”, “vertical”, “horizontal”, “inside”, “outside” indicate the orientation or positional relationship according to the orientation or positional relationship shown in the drawings, and are used for only facilitating the description of the present disclosure and simplifying the description, rather than indicating or implying the device or element must have a specific orientation and be constructed and operated in a specific orientation, so it cannot be understood as a limitation of the present disclosure. In addition, the terms such as “first”, “second”, and “third” are used for descriptive purposes only, and should not be interpreted as indicating or implying relative importance.

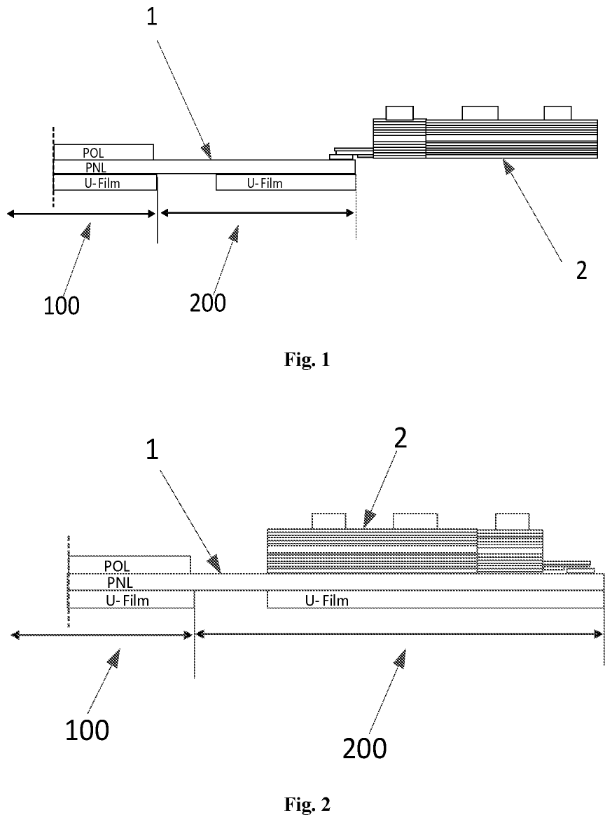

A display panel 1 generally includes a central display area 100 and a border area arranged at a periphery of the display area. The border area includes left and right borders, as well as top and lower borders 200. A binding area is arranged at the lower border 200. FIG. 1 is a schematic diagram of a conventional binding in related art. A flexible circuit board 2 only has a binding portion stacked on the lower border. FIG. 2 is a schematic diagram of reverse binding (the cover plate in FIG. 1 and FIG. 2 are not shown). A flexible circuit board 2 is stacked as a whole on the lower border, and the lower border needs sufficient space to accommodate the flexible circuit board 2, which cannot achieve a narrow border.

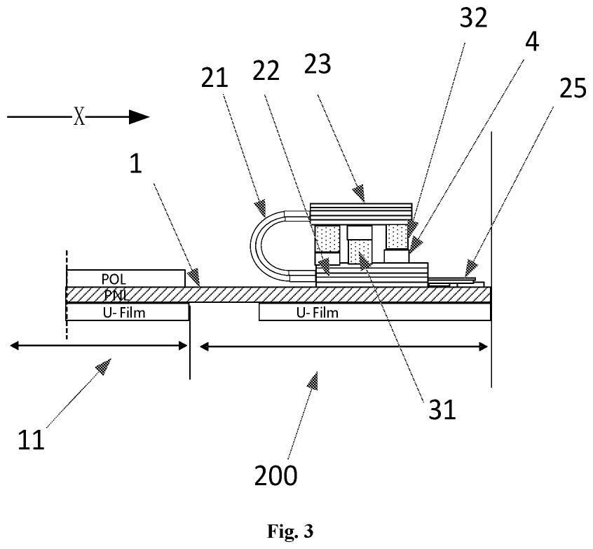

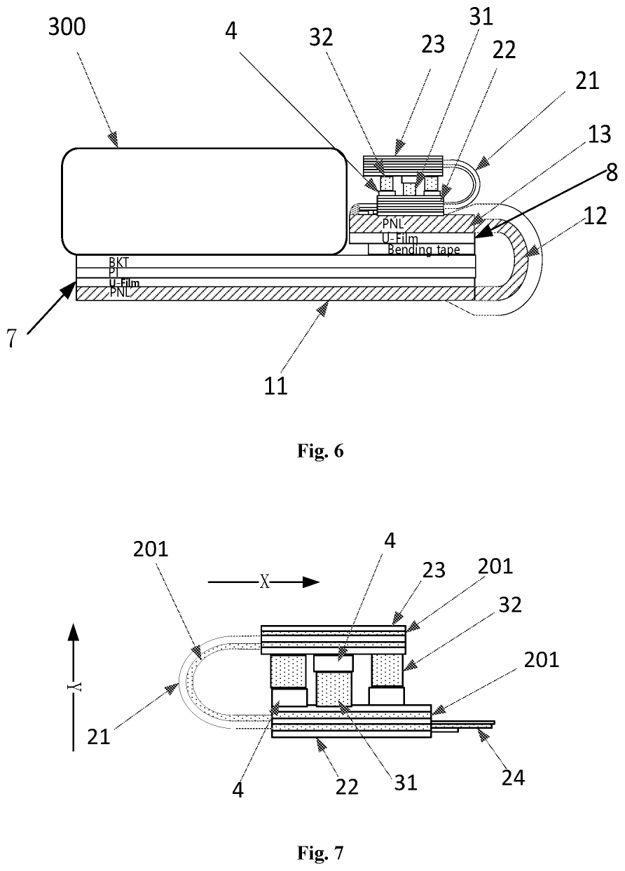

In view of the above problem, referring to FIG. 3 and FIG. 6, the embodiments of the present disclosure provide a display module, including a display panel 1 and a flexible circuit board 2 bound to the display panel 1. The display panel 1 includes a display area 11, a binding area 13, and a bending area 12 arranged between the display area 11 and the binding area 13. The bending area 12 is bent so that the binding area 13 is arranged at a backlight side of the display area 11. The flexible circuit board 2 includes a bending portion 21 and a first portion 22 and a second portion 23 arranged on respective two opposite sides of the bending portion 21. The first portion 22 is bound to the binding area 13, and an orthographic projection of the first portion 22 onto the binding area 13 is located within the binding area 13. The bending portion 21 is bent so that the second portion 23 is stacked on a side of the first portion 22 distal to the display panel 1.

FIG. 3 is a schematic diagram of the bending area 12 in a flattened state (the cover plate is not shown in FIG. 3), and FIG. 6 is a schematic diagram of the bending area 12 in a bent state. The display panel 1 includes a central display area and a border area arranged at the periphery of the display area. The border area includes left and right borders, as well as top and lower borders. A direction from the top border to the lower border 200 is defined as a first direction (referring to the X direction in FIG. 3), and the first direction is parallel to the display area 11. The binding area 13 is arranged at the lower border, and the flexible circuit board 2 is divided into a bending portion 21, a first portion 22 and a second portion 23, and the first portion 22 and the second portion 23 are arranged at two opposite sides of the bending portion 21 respectively. The bending portion 21 is bent so that the second portion 23 is stacked at a side of the first portion 22 distal to the display panel 1. In contrast to FIG. 1, the orthographic projection of the first portion 22 onto the binding area 13 is located within the binding area 13, and the first portion 22 not only includes a binding portion; when the bending portion 21 is in the bent state, the orthographic projection of the flexible circuit board as a whole onto the binding area 13 is located within the binding area 13. Referring to FIG. 3 and FIG. 6, the backlight side of the display panel is provided with a first back film layer 7 and a second back film layer 8. The gap between the first back film layer 7 and the second back film layer 8 corresponds to the bending area 12. The first portion 22 has a first end distal to the bending portion 21, and the distance from the first end to the bending axis of the bending portion 21 is the length of the flexible circuit board 2 in the first direction, which is equivalent to folding the conventional flexible circuit board 2. Therefore, the length of the lower border in the first direction is reduced, and the cost is saved as compared with a configuration where the flexible circuit board 2 directly adopts a multi-layer board structure (due to the lack of a bending portion 21 in the conventional multi-layer board structure, a same product needs to adopt a structure of more layers).

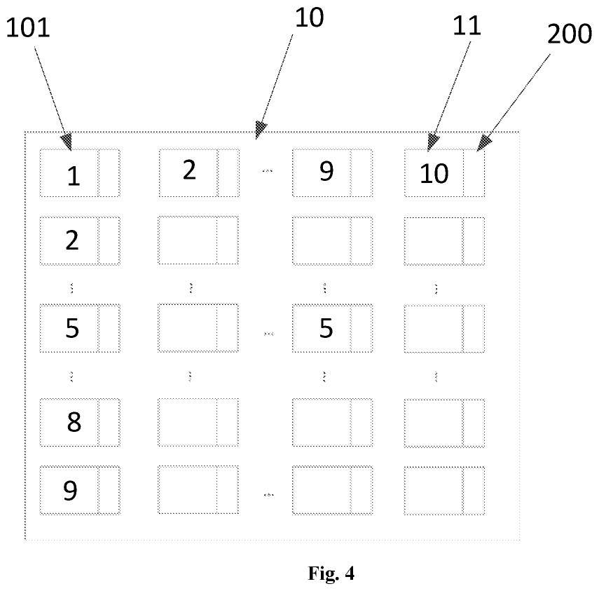

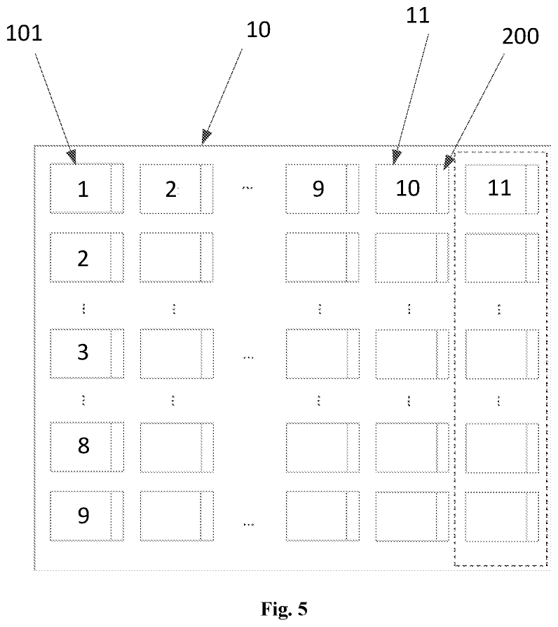

By adopting the above solution, the length of the lower border 200 in the first direction can be reduced by 4.5-5.5 mm, but this is not limited. Due to the reduction of the lower border, when arranging layouts on the motherboard 10, the layout rate is increased, and the number of EAC cuts (cutting quantity) for the sub-board 101 is increased. Referring FIG. 4 and FIG. 5, wherein FIG. 4 is a layout diagram of the flexible circuit board 2 according to the conventional binding method, and FIG. 5 is a layout diagram of the flexible circuit board 2 according to the arranging method of the embodiments of the present disclosure. It is obvious that due to the narrowing of the lower border 200, one more column of the sub-board 101 is arranged in the first direction (the column circled by the dashed line in FIG. 5), which increases the layout rate by 10% and the number of cuts by 9 EA/glass.

Referring to FIG. 7-FIG. 9, in an exemplary embodiment, the bending portion 21 includes a single circuit layer 201, the first portion 22 includes two or more circuit layers 201, and the second portion 23 includes two or more circuit layers 201.

The bending portion 21 adopts a single circuit layer 201, which may facilitate the bending of the bending portion 21. The first portion 22 and the second portion 23 are of multi-layer board structures, including two or more circuit layers 201, which may facilitate the distribution of the circuit.

It should be noted that the number of circuit layers 201 included in the first portion 22 and the number of circuit layers 201 included in the second portion 23 can be determined according to actual needs.

The number of circuit layers 201 included in the first portion 22 and the number of circuit layers 201 included in the second portion 23 can be the same or different. In an embodiment of the embodiments, the number of circuit layers 201 included in the first portion 22 and the number of circuit layers 201 included in the second portion 23 are the same. The first portion 22 includes two circuit layers 201, and the second portion 23 includes two circuit layers 201, but not limited to this.

For example, in the first portion 22 or the second portion 23, an insulation layer is arranged between adjacent layers of circuit layer 201.

In an exemplary embodiment, the first portion 22 includes a main body and a binding portion 24 extending from a part of the main body in a direction away from the bending portion 21. The binding portion 24 is bound to an end of the binding area 13 distal to the bending area 12, and the bending portion 21 is arranged at a side of the first portion 22 proximate to the bending area 12.

In an exemplary embodiment, an electronic device 3 is arranged between the first portion 22 and the second portion 23.

The electronic device 3 is arranged between the first portion 22 and the second portion 23. When the bending portion 21 is in the bent state, the electronic device 3 is arranged between the first portion 22 and the second portion 23. Compared to the arranging on the side of the second portion 23 distal to the first portion 22, the electronic device 3 is exposed to the outside, which protects the electronic device 3. Moreover, the electronic device 3 is arranged between the first portion 22 and the second portion 23, which also maintains the spacing between the first portion 22 and the second portion 23, ensuring the bent state of the bending portion 21.

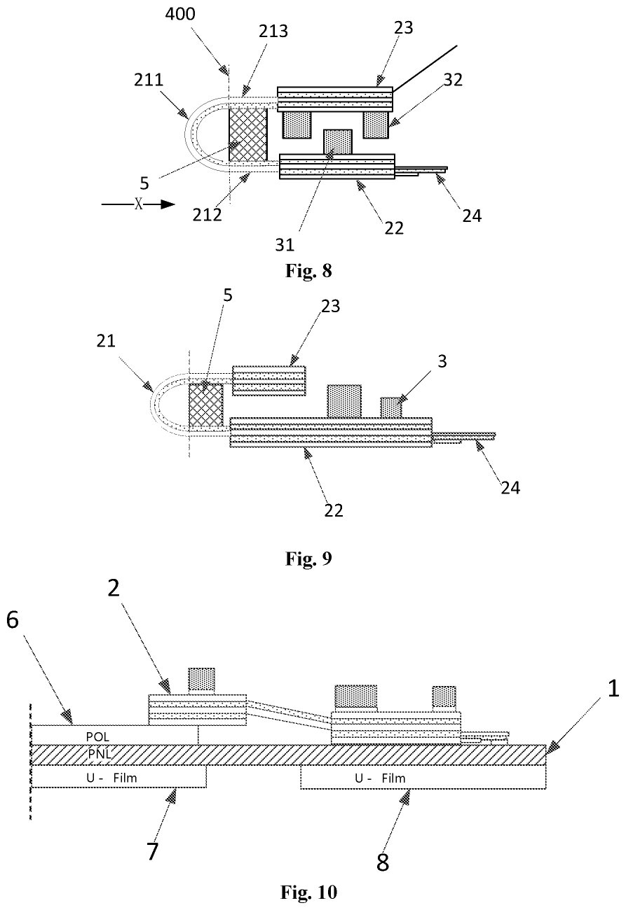

The electronic device 3 can be fixed to the first portion 22 or the second portion 23. The first portion 22 and the second portion 23 can be simultaneously provided with the electronic device 3. In an exemplary embodiment, the first portion 22 has a first surface facing the second portion 23, the second portion 23 has a second surface facing the first portion 22, a first electronic device is arranged on the first surface 31, and a second electronic device is arranged on the second surface 32. The first electronic devices 31 and the second electronic devices 32 are arranged in an alternating manner, as shown in FIG. 7 and FIG. 8.

In an exemplary embodiment, the orthographic projection of the first electronic device 31 onto the second surface is arranged between two adjacent second electronic devices 32.

In an exemplary embodiment, in a direction perpendicular to the first surface (referring to the Y direction in FIG. 7), the first electronic device 31 at least partially overlaps with the second electronic device 32, or there is a gap between the first electronic device 31 and the second electronic device 32.

In the direction perpendicular to the first surface, a sum of the thickness of the first electronic device 31 and the thickness of the second electronic device 32 is greater than the distance between the first surface and the second surface, that is, the first electronic device 31 at least partially overlaps with the second electronic device 32. In an embodiment, in the direction perpendicular to the first surface, the thickness of the first portion 22 is equal to the thickness of the second portion 23, and the thickness of the first portion 22 is equal to the distance between the first surface and the second surface.

In the direction perpendicular to the first surface, the sum of the thickness of the first electronic device 31 and the thickness of the second electronic device 32 is less than the distance between the first surface and the second surface, that is, there is a gap between the first electronic device 31 and the second electronic device 32.

In an embodiment, in the direction perpendicular to the first surface, the first electronic device 31 at least partially overlaps with the second electronic device 32, and the first electronic device 31 and the second electronic device 32 form an interlocking structure. When the bending portion 21 is in the bent state, the overall stability of the flexible circuit board 2 is enhanced, which can effectively reduce instances of peeling as well as damage like cracks caused by bumps, drops, or other impacts on the device.

In an exemplary embodiment, in a direction parallel to the first surface (referring to the X direction in FIG. 8), there is a gap between adjacent first electronic device 31 and second electronic device 32, or an insulation layer is arranged on the peripheral surface of the first electronic device 31, and/or an insulation layer is arranged on the peripheral surface of the second electronic device 32.

By adopting the above solution, it avoids issues such as short circuits occurring between adjacent first electronic device 31 and second electronic device 32.

In an exemplary embodiment, the number of first electronic devices 31 arranged on the first surface can be arranged according to actual needs, and the number of second electronic devices 32 arranged on the second surface can be arranged according to actual needs.

In an exemplary embodiment, multiple first electronic devices 31 are uniformly arranged on the first surface, and multiple second electronic devices 32 are uniformly arranged on the second surface.

In an exemplary embodiment, the widths of multiple first electronic devices 31 may be the same or different in the direction parallel to the first surface.

In an exemplary embodiment, the thicknesses of multiple first electronic devices 31 may be the same or different in the direction perpendicular to the first surface.

In an exemplary embodiment, the widths of multiple second electronic devices 32 may be the same or different in the direction parallel to the first surface.

In an exemplary embodiment, the thicknesses of multiple second electronic devices 32 may be the same or different in the direction perpendicular to the first surface.

In a specific implementation, in the direction parallel to the first surface (referring to the X direction in FIG. 8), the widths of multiple first electronic devices 31 and the widths of multiple second electronic devices 32 are the same, and the width of the first electronic device 31 is greater than or equal to 3 mm, but not limited to this.

In an exemplary embodiment, the orthographic projection of the second portion 23 onto the first portion 22 is located within a first region on the first portion 22, and the first portion 22 also has a second region for arranging the electronic device 3. In the first direction, the second region is adjacent to the first region, or the second region partially overlaps with the first region. The first direction is from the bending portion 21 to the first portion 22, and the first direction is parallel to the first surface.

In an exemplary embodiment, the electronic device 3 is fixed to the corresponding first portion 22 or second portion 23 by an adhesive layer 4. In the direction perpendicular to the first surface, the bending radius of the bending portion 21 is greater than or equal to half of a sum of the thickness of the adhesive layer 4 and the thickness of the corresponding electronic device 3, as shown in FIG. 7.

The arranging of the adhesive layer 4 can enhance the connection stability of the electronic device 3 and facilitate to ensure the bent state of the bending portion 21.

In an exemplary embodiment, in the direction parallel to the first surface (referring to the X direction in FIG. 7), the width of the adhesive layer 4 is greater than or equal to the width of the corresponding electronic device 3.

In an exemplary embodiment, in the direction perpendicular to the first surface (referring to the Y direction in FIG. 7), the thickness of the adhesive layer 4 is greater than or equal to 30% of the thickness of the corresponding electronic device 3. For example, the thickness of the adhesive layer 4 is greater than or equal to 0.3 mm, but not limited to this.

In an exemplary embodiment, the bending portion 21 includes an arc-shaped region 211, as well as a first planar region 212 and a second planar region 213 arranged at two opposite sides of the arc-shaped region 211, respectively. In the direction perpendicular to the first surface, a supporting adhesive layer 5 is arranged between the first planar region 212 and the second planar region 213, as shown in FIG. 8.

The arranging of the supporting adhesive layer 5 ensures the bent state of the bending portion 21, and prevents warping of the bending portion 21.

In an exemplary embodiment, a side surface of the supporting adhesive layer 5 proximate to the arc-shaped region 211, a bending start point of the arc-shaped region and a bending end point of the arc-shaped region 21 are arranged on a same plane perpendicular to the first surface (referring to the position of the dashed line 400 in FIG. 8).

By adopting the above solution, the supporting adhesive layer 5 ensures the starting and ending points of bending of the arc-shaped portion 21, and prevents warping of the bending portion 21.

In an exemplary embodiment, a first protective adhesive layer is arranged at a side of the first portion 22 proximate to the second portion 23, and a second protective adhesive layer is arranged at a side of the second portion 23 proximate to the first portion 22. The electronic device 3 is arranged on the first protective adhesive layer and/or the second protective adhesive layer. The thickness of the supporting adhesive layer 5 is greater than or equal to the thickness of the electronic device 3 in the direction perpendicular to the first surface.

In this implementation, the thickness of the supporting adhesive layer 5 is greater than or equal to the distance between the first surface and the second surface, which ensures the supporting adhesive layer 5 supports the bending portion 21 effectively. The electronic device 3 is arranged between the first surface and the second surface, and the thickness of the electronic device 3 is equal to the distance between the first surface and the second surface, that is, the thickness of the supporting adhesive layer 5 is greater than or equal to the thickness of the electronic device 3.

It should be noted that in the direction perpendicular to the first surface, the thickness of the supporting adhesive layer 5 is related to the thickness of the electronic device 3 or the distance between the first surface and the second surface. In the implementation of arranging the first electronic device 31 on the first surface and arranging the second electronic device 32 on the second surface, in the direction perpendicular to the first surface, the thickness of the first electronic device 31 and the thickness of the second electronic device 32 can be equal, and the thickness of the first electronic device 31 is equal to the distance between the first surface and the second surface. If the thickness of the first electronic device 31 is different from the thickness of the second electronic device 32, the thickness of the supporting adhesive layer 5 is greater than or equal to the distance between the first surface and the second surface.

It should be noted that the first portion 22 has a third surface far away from the second portion 23, and the second portion 23 has a fourth surface far away from the first portion 22. In the direction perpendicular to the first surface, the thickness of the supporting adhesive layer 5 is less than or equal to the distance between the third surface and the fourth surface, and the bending diameter of the bending portion 21 is less than or equal to the distance between the third surface and the fourth surface.

It should be noted that when the bending area 12 is in the bent state, in the direction perpendicular to the display area 11, a sum of the thickness of the binding area 13, the thickness of the second back film layer, and the overall thickness of the flexible circuit board 2 is less than the thickness of a battery 300, so as to prevent the assembly of the battery 300 from being adversely affected, as shown in FIG. 6.

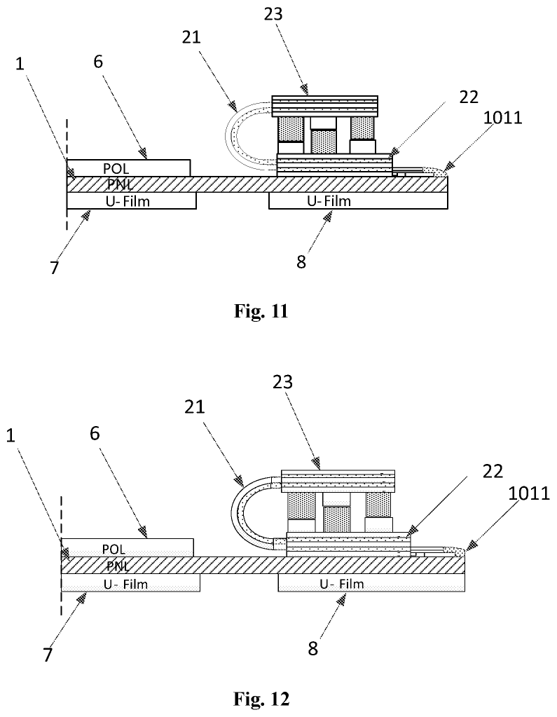

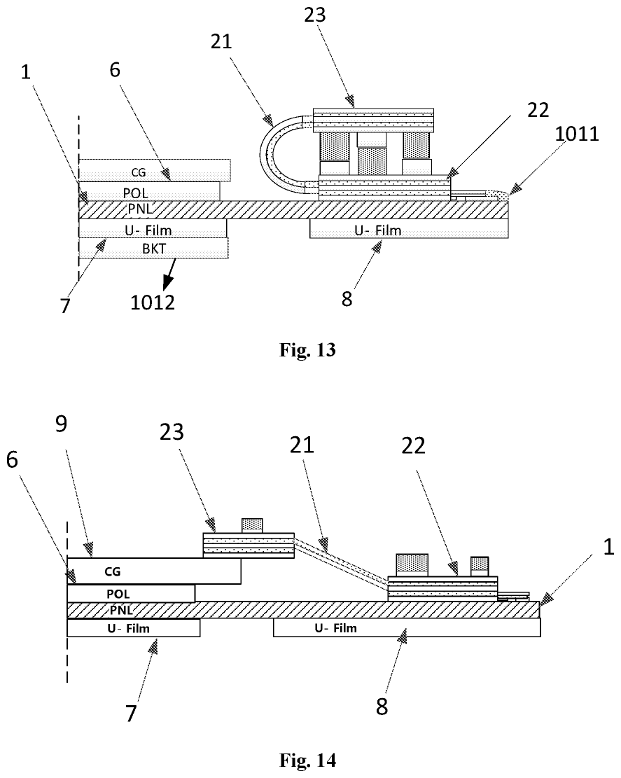

In a process of manufacturing the display module, the following steps are included:
attaching a polarizer on the light-emitting side of the display panel 1, attaching a first back film layer on the backlight side of the display area 11 of the display panel 1, and attaching a second back film layer on the binding area 13 of the display panel 1. The first back film layer and the second back film layer are arranged at a same side of the display panel 1 (the bending area 12 of the display panel 1 is in a flattened state);
reverse binding a flexible circuit board 2 to the display panel 1, as shown in FIG. 10;
arranging a protective adhesive layer 1011 between a binding portion 24 of the flexible circuit board 2 and the binding area 13 of the display panel 1, as shown in FIG. 11;
bending the bending portion 21 of the flexible circuit board 2 so that a first portion 22 and a second portion 23 of the flexible circuit board 2 are overlapped, as shown in FIG. 11;
cutting the lower border of the display panel 1 (the binding area 13 is arranged on the lower border), as shown in FIG. 12;
attaching a cover plate 9 on a side of the polarizer distal to the display panel 1;
attaching a supporting structure 1012 on the side of the first back film layer 7 distal to the display panel 1, as shown in FIG. 13;
bending the bending area 12 of the display panel 1, so that the binding area 13 is arranged on the backlight side of the display area 11.

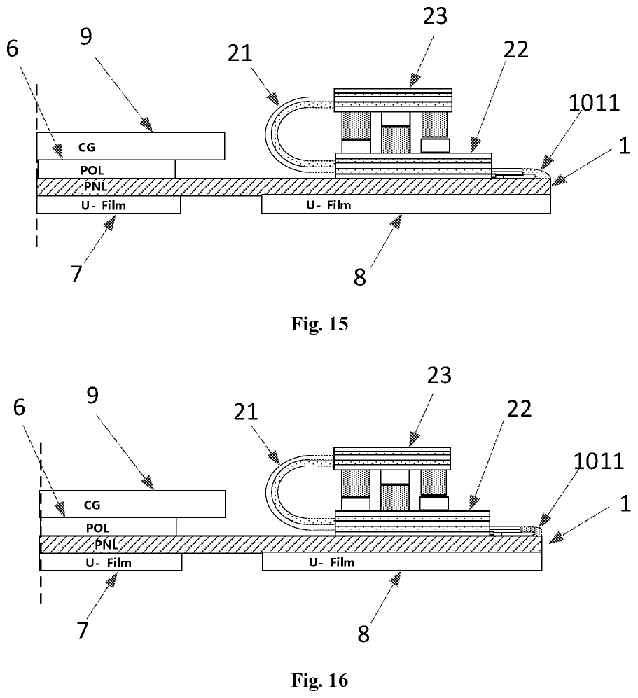

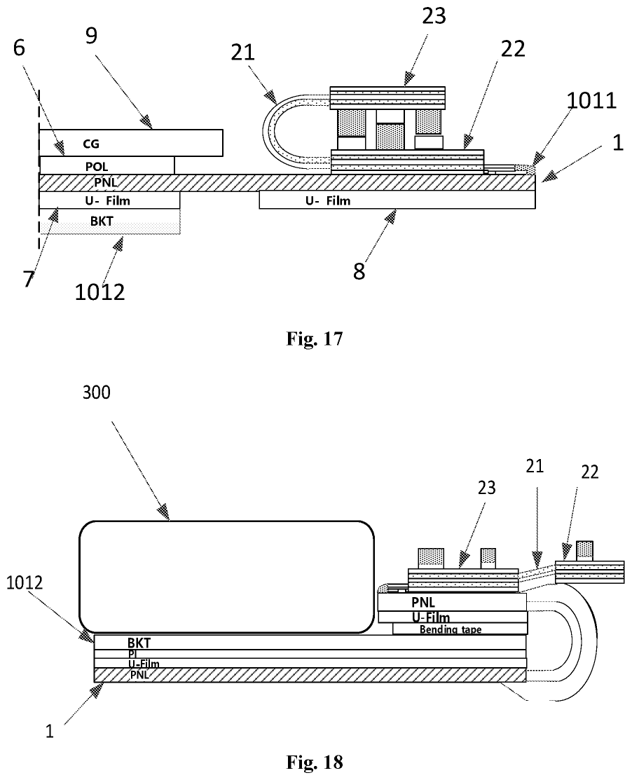

In an implementation, a process of manufacturing the display module includes the following steps:
attaching a polarizer and a cover plate on the light-emitting side of the display panel 1 sequentially in that order, attaching a first back film layer 7 on the backlight side of the display area 11 of the display panel 1, and attaching a second back film layer 8 on a binding area 13 of the display panel 1. The first back film layer 7 and the second back film layer 8 are arranged on the same side of the display panel 1 (the bending area 12 of the display panel 1 is in a flattened state);
reverse binding a flexible circuit board 2 to the display panel 1, as shown in FIG. 14;
arranging a protective adhesive layer 1011 between a binding portion 24 of the flexible circuit board 2 and the binding area 13 of the display panel 1, as shown in FIG. 15;
bending the bending portion 21 of the flexible circuit board 2, so that a first portion 22 and a second portion 23 of the flexible circuit board 2 are overlapped;
cutting the lower border of the display panel 1 (the binding area 13 is arranged on the lower border), as shown in FIG. 16;
attaching a supporting structure 1012 on the side of the first back film layer 7 distal to the display panel 1, as shown in FIG. 17;
bending the bending area 12 of the display panel 1, so that the binding area 13 is arranged on the backlight side of the display area 11.

In an implementation, a process of manufacturing the display module includes the following steps:
attaching a polarizer and a cover plate on the light-emitting side of a display panel 1 sequentially in that order, attaching a first back film layer 7 on the backlight side of the display area 11 of the display panel 1, and attaching a second back film layer 8 on a binding area 13 of the display panel 1. The first back film layer 7 and the second back film layer 8 are arranged on the same side of the display panel 1 (the bending area 12 of the display panel 1 is in a flattened state);
reverse binding a flexible circuit board 2 to the display panel 1;
arranging a protective adhesive layer 1011 between a binding portion 24 of the flexible circuit board 2 and the binding area 13 of the display panel 1;
cutting the lower border of the display panel 1 (the binding area 13 is arranged on the lower border);
attaching a supporting structure 1012 on a side of the first back film layer distal to the display panel 1;
bending the bending area 12 of the display panel 1, so that the binding area 13 is arranged on the backlight side of the display area 11, as shown in FIG. 18;
bending a bending portion 21 of the flexible circuit board 2, so that a first portion 22 and a second portion 23 of the flexible circuit board 2 are overlapped.

It should be noted that FIG. 1 to FIG. 18 are all schematic diagrams, and the AA area is not shown. There is a connecting layer between adjacent film layers such as the cover plate, the display panel 1, the polarizer 6, the first back film layer 7, and the second back film layer 8, which can be an optical adhesive layer, a pressure-sensitive adhesive layer, etc., but it is not shown in the drawings.

The embodiments of the present disclosure also provide a display device, including the foregoing display module.

It can be understood that the above embodiments of the present disclosure are merely exemplary embodiments used for illustrating the principle of the present disclosure, and the present disclosure is not limited thereto. For those of ordinary skill in the art, various modifications and improvements may be made without departing from the spirit and essence of the present disclosure, and these variations and improvements are also deemed to be within the protection scope of the present disclosure.

1. A display module, comprising a display panel and a flexible circuit board bound to the display panel, the display panel comprises a display area, a binding area, and a bending area arranged between the display area and the binding area, the bending area is bent to enable the binding area to be located at a backlight side of the display area,
wherein the flexible circuit board comprises a bending portion, a first portion and a second portion, the first portion and the second portion are arranged at opposite sides of the bending portion respectively, the first portion is bound to the binding area, an orthographic projection of the first portion onto the binding area is located within the binding area, the bending portion is bent to enable the second portion to be stacked at a side of the first portion distal to the display panel.

2. The display module according to claim 1, wherein the bending portion comprises a single circuit layer, the first portion comprises two or more circuit layers, and the second portion comprises two or more circuit layers.

3. The display module according to claim 1, wherein the first portion comprises a main body and a binding portion extending from the main body toward a direction away from the bending portion, the binding portion is bound to an end of the binding area distal to the bending area, and the bending portion is arranged at a side of the first portion proximate to the bending area.

4. The display module according to claim 1, wherein an electronic device is arranged between the first portion and the second portion.

5. The display module according to claim 4, wherein the first portion has a first surface facing the second portion, the second portion has a second surface facing the first portion, a first electronic device is arranged on the first surface, and a second electronic device is arranged on the second surface, the first electronic devices and the second electronic devices are arranged in an alternating manner.

6. The display module according to claim 5, wherein an orthographic projection of the first electronic device onto the second surface is located between two adjacent second electronic devices.

7. The display module according to claim 5, wherein in a direction perpendicular to the first surface, the first electronic device at least partially overlaps with the second electronic device, or there is a gap between the first electronic device and the second electronic device.

8. The display module according to claim 5, wherein in a direction parallel to the first surface, there is a gap between the first electronic device and the second electronic device that are adjacent to each other, or an insulation layer is arranged on a peripheral surface of the first electronic device, and/or an insulation layer is arranged on a peripheral surface of the second electronic device.

9. The display module according to claim 5, wherein an orthographic projection of the second portion onto the first portion is located within a first region on the first portion, and the first portion also has a second region for arranging the electronic device; in a first direction, the second region is adjacent to the first region, or the second region partially overlaps with the first region, wherein the first direction is from the bending portion toward the first portion, and the first direction is parallel to the first surface.

10. The display module according to claim 5, wherein the electronic device is fixed to the corresponding first portion or second portion by an adhesive layer; in a direction perpendicular to the first surface, a bending radius of the bending portion is greater than or equal to half of a sum of a thickness of the adhesive layer and a thickness of the corresponding electronic device.

11. The display module according to claim 5, wherein the bending portion comprises an arc-shaped region, a first planar region and a second planar region, the first planar region and the second planar region are arranged at two opposite sides of the arc-shaped region respectively; in a direction perpendicular to the first surface, a supporting adhesive layer is arranged between the first planar region and the second planar region.

12. The display module according to claim 11, wherein a side surface of the supporting adhesive layer proximate to the arc-shaped region, a bending start point of the arc-shaped region and a bending end point of the arc-shaped region are arranged in a same plane that is perpendicular to the first surface.

13. The display module according to claim 11, wherein a first protective adhesive layer is arranged at a side of the first portion proximate to the second portion, a second protective adhesive layer is arranged at a side of the second portion proximate to the first portion, the electronic devices are arranged on the first protective adhesive layer and/or the second protective adhesive layer, and a thickness of the supporting adhesive layer is greater than or equal to a thickness of the electronic device in a direction perpendicular to the first surface.

14. A display device, comprising the display module according to claim 1.

15. The display device according to claim 14 wherein the bending portion comprises a single circuit layer, the first portion comprises two or more circuit layers, and the second portion comprises two or more circuit layers.

16. The display device according to claim 14, wherein the first portion comprises a main body and a binding portion extending from the main body toward a direction away from the bending portion, the binding portion is bound to an end of the binding area distal to the bending area, and the bending portion is arranged at a side of the first portion proximate to the bending area.

17. The display device according to claim 14, wherein an electronic device is arranged between the first portion and the second portion.

18. The display device according to claim 17, wherein the first portion has a first surface facing the second portion, the second portion has a second surface facing the first portion, a first electronic device is arranged on the first surface, and a second electronic device is arranged on the second surface, the first electronic devices and the second electronic devices are arranged in an alternating manner.

19. The display device according to claim 18, wherein an orthographic projection of the first electronic device onto the second surface is located between two adjacent second electronic devices.

20. The display device according to claim 18, wherein in a direction perpendicular to the first surface, the first electronic device at least partially overlaps with the second electronic device, or there is a gap between the first electronic device and the second electronic device.
